(19) United States
(12) Patent Application Publication
(10) Pub. No.: US 2015/0191249 A1
(43) Pub. Date: Jul. 9, 2015

(54) FLEXIBLE ELECTRO-MECHANICAL ACTUATOR AND FLEXING BODIES

(71) Applicant: Parviz Acquisitions LLC, Los Angeles, CA (US)

(72) Inventors: Brandon Bridgeford, Alta Loma, CA (US); Mark Bridgeford, Alta Loma, CA (US)

(73) Assignee: Parviz Acquisitions LLC

(21) Appl. No.: 14/418,275

(22) PCT Filed: Jul. 31, 2013
(86) PCT No.: PCT/US13/53078

§ 371 Date: Jan. 29, 2015

Related U.S. Application Data
(60) Provisional application No. 61/678,466, filed on Aug. 1, 2012.

(51) Int. Cl. B64D 15/16; H01L 41/12; B60S 1/08

(52) U.S. Cl. CPC B64D 15/163; B60S 1/08; H01L 41/12

(57) ABSTRACT

An electro-expulsive actuator capable of operating while encased within a flexible member is provided. The electro-expulsive actuator is designed to be resiliently flexible such that the flexible member remains fully deformable along its length. In addition, rather than striking the surface of or creating a shockwave within the flexible member, the actuator is disposed within the flexible member such that the deformation of the electro-expulsive actuator itself causes deformation of the flexible member thereby causing unwanted build-up of residues on the outer surface of the flexible member to be disrupted.

### FIELD OF THE INVENTION

The present invention generally relates to electro-mechanical actuators; and more particularly to electro-mechanical actuators capable of being used within elastically flexible members, and to self-flexing flexible members.

### BACKGROUND

An “electro-expulsive actuator”, also sometimes referred to as an “electro-mechanical expulsive actuator”, as used for example, in the breakup or removal of unwanted residue build up from an object, uses electrically produced mechanical motion to produce a shockwave in the surface of the object where the residue build-up is present. These types of devices are particularly useful in applications where the surface of the object to be cleared is either inaccessible or hazardous, such as, for example, deicing the wing of an aircraft during flight.

A typical electro-expulsive system includes electro-mechanical transducers called “actuators” that are installed beneath the outer surface of an object (e.g., in an aircraft the leading edges of wings, horizontal and vertical stabilizers, and engine inlets). An electronic control system then passes large current pulses through such actuators (e.g., thousands of amperes expelled in pulses having millisecond durations pulses at predetermined intervals) in order to thereby produce mechanical motion that produces shock waves in the surface of the object. The shock waves result in breakup and/or dislodgement of the undesirable residue (such as, for example, ice) that has accumulated on the object surface. In short, the actuator imparts energy to the inner surface of the object, that action produces the shock waves in the object surface, and the shock waves interact with the accumulated residue on the surface of the object.

Some such existing electro-expulsive actuators include strips or ribbons of copper or other electrically conductive material that are mounted in closely-spaced-apart parallel orientation. Electric current flowing as mentioned above causes the strips to accelerate apart from each other in a manner creating residue-removing shock waves. The electrically conductive strips for some actuators take the form of a copper ribbon wrapped in an elongated multi-turn loop (i.e., a multi-turn coil). A copper ribbon measuring, for example, 0.25 inches to 1.50 inches wide and 0.020 inches to 0.040 inches thick, is wrapped in a multilayer, elongated, loop measuring about one to eight feet in length, with the copper ribbon being wound back on itself at the ends of the loop. In some of these devices, molded blocks of polyurethane encapsulate the two opposite folded ends of the loop while a dielectric coating on the copper ribbon prevents shorting between adjacent turns. Interconnection of the copper ribbon loop to the onboard electronic control system results in electric current pulses flowing in a first direction in a first half of the loop (from a first folded end of the loop to an opposite second folded end), and in an opposite second direction in a second half of the loop (from the second folded end of the loop to the first folded end). As an electric current pulse flows that way, it results in a large force that tends to mutually repel the first and second halves of the loop. That repulsion results in relative movement of the first and second halves away from each other in a pulse of mechanical motion that is coupled to the surface of an object. That mechanical pulse results in the residue breakup/removal shock waves.

Although effective in many respects, some existing actuators of the type described above have certain drawbacks that need to be overcome. First, impact of the skin can be less than desired for adequate residue breakup/removal. Actuator operation is sometimes less robust than desired. In addition, the ends of the loop tend to experience fatigue failure. Recently a new electro-expulsive actuator has been described predicated on a realization that somewhat reduced performance and fatigue failure are a result of the encapsulated loop ends being fixed and unmovable relative to each other (with essentially a near zero radius at the fold), and that resolves the performance issue by including an electrically conductive loop formed by two mechanically independent loop subassemblies. (See, e.g., U.S. Pat. Pub. No. 2010/0288882, the disclosure of which is incorporated herein by reference.)

Although these advanced systems do address the performance issues with many conventional fixed electro-expulsive actuators, these systems have typically been limited to actuators designed to be attached to a rigid or semi-rigid object against which the actuator moves or strikes to produce the shock waves. However, there is a need for electro-expulsive actuators capable of disrupting and/or removing residue (such as, for example, ice) from the surfaces of resiliently flexible members.

### SUMMARY OF THE INVENTION

The current invention is directed to an electro-expulsive actuator capable of operating while encased within a flexible member, and methods of providing an electro-expulsive force by the direct flexing of the actuator.

In some embodiments the invention is directed to an actuator for an electro-expulsive residue disruption apparatus including:
a first sub-assembly comprising a first electrically conductive element coupled to an electrical input at a first end of the first electrically conductive element;
a second sub-assembly comprising a second electrically conductive element coupled to an electrical output at a first end of the second electrically conductive element;
wherein the first and second sub-assemblies are independent;
a separate electrically conductive connector connecting a second end of the first electrically conductive element of the first sub-assembly to a corresponding second end of the second electrically conductive element of the second sub-assembly, thereby creating a conductive path from the electrical input to the electrical output, and wherein the connector is configured to allow the second end of the first sub-assembly and the second end of the second sub-assembly to move apart relative to each other;
wherein at least the first and second sub-assemblies, and the connector are embedded within a flexible member; and
wherein the first and second sub-assemblies are disposed in an orientation such that when electrical current flows through the conductive loop, at least a portion of each of the first and second sub-assemblies move apart relative to one another as a result of the magnetic fields created by the electrical current in the first and second sub-assemblies thereby causing the flexible member to undergo a flexural deformation.

In other embodiments the invention is directed to a method of disrupting residue including:
inducing an electrical current in an object comprising an actuator for an electro-expulsive residue disruption apparatus, the object comprising an actuator for the electro-expulsive disruption apparatus embedded within a flexible member including:
a first sub-assembly comprising a first electrically conductive element coupled to an electrical input at a first end of the first electrically conductive element;
a second sub-assembly comprising a second electrically conductive element coupled to an electrical output at a first end of the second electrically conductive element;
wherein the first and second sub-assemblies are mechanically independent.
a separate electrically conductive connector connecting a second end of the first electrically conductive element of the first sub-assembly to a corresponding second end of the second electrically conductive element of the second sub-assembly, thereby creating a conductive path from the electrical input to the electrical output, and wherein the connector is configured to allow the second end of the first sub-assembly and the second end of the second sub-assembly to move apart relative to each other;
wherein at least the first and second sub-assemblies, and the connector are embedded within a flexible member; and
wherein the first and second sub-assemblies are disposed in an orientation such that when electrical current flows through the conductive loop, at least a portion of each of the first and second sub-assemblies move apart relative to one another as a result of the magnetic fields created by the electrical current in the first and second sub-assemblies thereby causing the flexible member to undergo a flexural deformation.

In still other embodiments, the invention is directed to a self-flexing flexible member including:
an elongated flexible body;
a flexible actuator contained within said body and including:
a first sub-assembly comprising a first electrically conductive element coupled to an electrical input at a first end of the first electrically conductive element,
a second sub-assembly comprising a second electrically conductive element coupled to an electrical output at a first end of the second electrically conductive element,
wherein the first and second sub-assemblies are independent,
a separate electrically conductive connector connecting a second end of the first electrically conductive element of the first sub-assembly to a corresponding second end of the second electrically conductive element of the second sub-assembly, thereby creating a conductive path from the electrical input to the electrical output, and wherein the connector is configured to allow the second end of the first sub-assembly and the second end of the second sub-assembly to move apart relative to each other;
wherein at least the first and second sub-assemblies, and the connector are embedded within a flexible member, and
wherein the first and second sub-assemblies are disposed in an orientation such that when electrical current flows through the conductive loop, at least a portion of each of the first and second sub-assemblies move apart relative to one another as a result of the magnetic fields created by the electrical current in the first and second sub-assemblies; and
wherein the flexible actuator is disposed within the flexible body such that movement of the actuator causes the flexible body to undergo a flexural deformation.

In some of the above embodiments the first sub-assembly comprises a plurality of electrically conductive elements in a substantially stacked, parallel configuration.

In other of the above embodiments the second sub-assembly comprises a plurality of electrically conductive elements in a substantially stacked, parallel configuration.

In still other of the above embodiments the connector is one of a plurality of connectors connecting second ends of pairs of electrically conductive elements, each pair comprising an electrically conductive element from the first sub-assembly element and an electrically conductive element from the second sub-assembly.

In yet other of the above embodiments a second plurality of connectors connecting first ends of pairs of electrically conductive element, each pair comprising an electrically conductive element from the first sub-assembly and an electrically conductive element from the second sub-assembly.

In still yet other of the above embodiments the connector is flexible and is selected from the group consisting of a wire and a U-shaped loop.

In still yet other of the above embodiments a longitudinal axis of the connector is parallel to a longitudinal axis of the conductive elements.

In still yet other of the above embodiments a longitudinal axis of the connector is perpendicular to a longitudinal axis of the conductive elements.

In still yet other of the above embodiments the at least the first and second sub-assemblies, and the connector are embedded within an internal cavity formed into the body of the flexible member.

In still yet other of the above embodiments the flexible member is integrally formed around the at least the first and second sub-assemblies, and the connector.

In still yet other of the above embodiments at least the electrical input and electrical output provide an electrical contact that extends outside of the flexible member.

In still yet other of the above embodiments the flexible member is selected from the group consisting of a wiper blade, a gasket, a seal, and a resilient member.

In still yet other of the above embodiments the actuator is flexible such that it conforms to the shape of the flexible member during actuation and deformation of the flexible body.

### BRIEF DESCRIPTION OF THE DRAWINGS

The description will be more fully understood with reference to the following figures, which are presented as exemplary embodiments of the invention and should not be construed as a complete recitation of the scope of the invention, wherein:

FIG. 1 illustrates a first view of a flexible electro-expulsive actuator in accordance with an embodiment of the invention.

FIG. 2 depicts a cross-sectional schematic of a flexible electro-expulsive actuator in accordance with an embodiment of the invention.

FIG. 3 illustrates a second view of a flexible electro-expulsive actuator in accordance with an embodiment of the invention.

### DETAILED DESCRIPTION

Turning now to the drawings, an electro-expulsive actuator capable of operating while encased within a flexible member and self-flexing resilient members are described. Importantly, the electro-expulsive actuators of the current invention are designed to be resiliently flexible, such that the flexible member remains fully deformable along its length, but simultaneously capable of self-flexing. In addition, rather than striking the surface of or creating a shockwave within the flexible member, the actuator of the current invention is disposed within the flexible member such that the deformation or flexing of the electro-expulsive actuator itself causes deformation or flexing of the flexible member thereby causing the disruption, and in some cases removal, of unwanted residues on the outer surface of the flexible member.

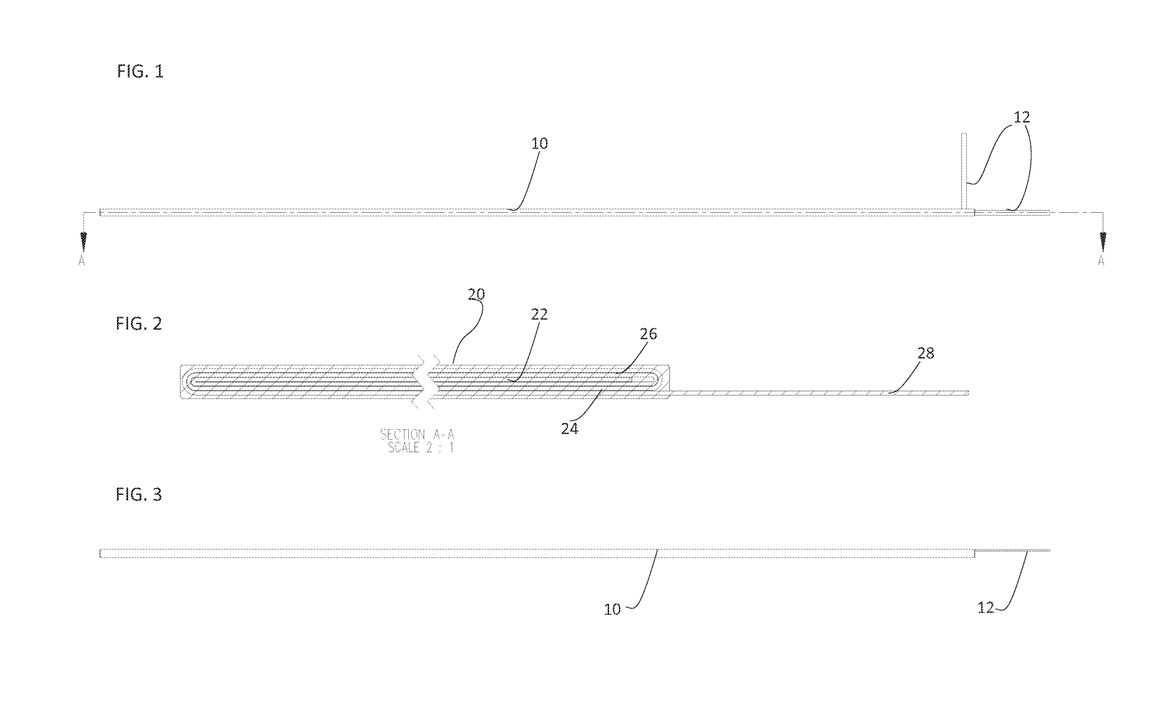

FIGS. 1 and 2 of the drawings provide schematic representations of a flexible/resilient member incorporating flexible electro-expulsive actuator in accordance with some embodiments. Generally, the flexible member (10) is provided as part of a system that would include an electronic control system (not shown), i.e., an electro-expulsive control system connected electrical leads (12) to an actuator (not shown) that is mounted or encased within the flexible member. It should be understood that the flexible member itself may be of any form, shape and length capable of fully encasing the actuator (e.g., a windshield wiper blade or a seal, gasket or other resilient sealing member), and the system operates to disrupt and/or remove residue, such as ice or other materials (not shown) that has formed on the outer surface of the flexible member. The actuator responds to electronic pulses from the control system by flexing the surrounding flexible member, thereby producing movement along the outer surface of the flexible member to disrupt and/or remove residue that has formed on an outwardly facing surface of the flexible member. Moreover, because the actuator itself is flexible, it can operate in any conformation or outer curved shape into which the flexible member is bent.

It should be understood that though a few examples of flexible members have been briefly described above, the actuator of the instant invention may be encased within any flexible member capable of containing it. Further, the bonding or encasing of the actuator within the flexible member, and the provision of suitable electrical leads can take any suitable form depending on the application and materials required for the operation of the flexible material. For example, the flexible member could be formed around and in direct contact with the actuator, such as by coating or casting or molding a resilient plastic material therearound. Alternatively, the actuator could be inserted within a channel formed separately within the flexible member. In short, any method could be used to integrate or encase the actuator within the flexible member so long as deformation of the actuator causes direct deformation of the flexible member sufficient to remove any unwanted residue on the outer surface of the flexible member regardless of the conformation into which the flexible member is placed.

FIG. 2 shows a cross-section of a flexible member (20) incorporating an actuator (22) constructed in accordance with embodiments of this disclosure. The actuator includes a first subassembly (24) having electrically conductive elements and a second subassembly (26) having electrically conductive elements. The electrically conductive elements of the first and second subassemblies and are connected in a multi-turn electrically conductive loop (i.e., a multi-turn coil) beginning and terminating at externally connectable leads (28). This electrically conductive loop carries movement-producing electric pulses, but it also allows the ends of first and second subassemblies and freedom of movement. As a result, actuator performance is improved and fatigue failure is avoided.

In one embodiment, the multiple conductive elements may be interconnected by flexible connectors taking the form of jumper wires fabricated from lengths of wire, such as stranded wire. The connectors serve as means electrically interconnecting various ones of the terminal ends of the elements in order to thereby form the electrically conductive loop. The connectors in such an embodiment are soldered or otherwise suitably connected to the ends of the elements. In an alternative embodiment, the connectors of the actuator are sections of conductive ribbon in U-shaped configurations (e.g., similar in width and thickness to the ribbon composition of the electrically conductive elements of the first and second subassemblies. Regardless of the interconnection chosen, the connectors form U-shaped loops to minimize the restrictive effect of the mid portion on relative movement of the first and second subassemblies. In still another embodiment, (not shown) the axes of elongation of the connectors may be oriented so that their axes of elongation are perpendicular to the direction of elongation of the electrically conductive loop. That connector orientation is important in some installations for reducing the overall length of the actuator. (See, e.g., U.S. Pat. Pub. No. 2010-0288882A1, the disclosure of which is incorporated herein by reference.)

In order to ensure the actuator's ability to provide flexible actuation, it is important that both the actuator itself and the flexible member in which it is encased be formed of materials and disposed such that they can conform as necessary to the external environment into which the flexible member is to be placed and still provide electro-expulsive actuation. In addition, the flexible member should be deformable such that when actuated it undergoes flexural deformation. In addition, in some embodiments the actuator itself may flex along its longitudinal length (in either a parallel and/or perpendicular direction). In this regard, the conductive loops of the actuator and any connectors formed therewith should be made of a flexible conductive material with good fatigue and strain resistance, such as, for example, thin strips of a ductile conducting metal, such as, for example, copper, aluminum, etc. Likewise, the flexible outer casing that makes up the surrounding body of the flexible member should be formed of a suitable flexible non-conducting material, such as, for example, plastics, rubbers, etc.

During operation, the control system provides movement-producing electric current pulses to the actuator subassemblies that cause the first and second subassemblies to move apart thereby forcefully deforming the flexible member regardless of its conformation at that moment and doing so with a pulse of mechanical energy that creates residue-disrupting movement in the outer surface of the flexible member. (Such as is described in greater detail in U.S. Pat. Pub. No. 2010-0288882A1, cited above.) Importantly, because of the flexible nature of the actuator and the encasing member, the actual expulsive force is generated directly by the movement or flexing of the actuator translated into the movement or flexing of the flexible member.

Thus, the invention provides an electro-expulsive actuator that alleviates performance and fatigue failure concerns of the prior art and also is flexible such that it can provide actuation in virtually any configuration, and to self-flexing resilient or flexible members.

### DOCTRINE OF EQUIVALENTS

Those skilled in the art will appreciate that the foregoing examples and descriptions of various preferred embodiments of the present invention are merely illustrative of the invention as a whole, and that variations in the steps and various components of the present invention may be made within the spirit and scope of the invention. Accordingly, the present invention is not limited to the specific embodiments described herein but, rather, is defined by the scope of the appended claims.

What is claimed:

1. An actuator for an electro-expulsive residue disruption apparatus comprising:
a first sub-assembly comprising a first electrically conductive element coupled to an electrical input at a first end of the first electrically conductive element;
a second sub-assembly comprising a second electrically conductive element coupled to an electrical output at a first end of the second electrically conductive element;
wherein the first and second sub-assemblies are independent;
a separate electrically conductive connector connecting a second end of the first electrically conductive element of the first sub-assembly to a corresponding second end of the second electrically conductive element of the second sub-assembly, thereby creating a conductive path from the electrical input to the electrical output, and wherein the connector is configured to allow the second end of the first sub-assembly and the second end of the second sub-assembly to move apart relative to each other;
wherein at least the first and second sub-assemblies, and the connector are embedded within a flexible member; and
wherein the first and second sub-assemblies are disposed in an orientation such that when electrical current flows through the conductive loop, at least a portion of each of the first and second sub-assemblies move apart relative to one another as a result of the magnetic fields created by the electrical current in the first and second sub-assemblies thereby causing the flexible member to undergo a flexural deformation.

2. The actuator of claim 1, wherein the first sub-assembly comprises a plurality of electrically conductive elements in a substantially stacked, parallel configuration.

3. The actuator of claim 2, wherein the second sub-assembly comprises a plurality of electrically conductive elements in a substantially stacked, parallel configuration.

4. The actuator of claim 3, wherein the connector is one of a plurality of connectors connecting second ends of pairs of electrically conductive elements, each pair comprising an electrically conductive element from the first sub-assembly element and an electrically conductive element from the second sub-assembly.

5. The actuator of claim 4, further comprising a second plurality of connectors connecting first ends of pairs of electrically conductive element, each pair comprising an electrically conductive element from the first sub-assembly and an electrically conductive element from the second sub-assembly.

6. The actuator of claim 1, wherein the connector is flexible and is selected from the group consisting of a wire and a U-shaped loop.

7. The actuator of claim 1, wherein a longitudinal axis of the connector is parallel to a longitudinal axis of the conductive elements.

8. The actuator of claim 1, wherein a longitudinal axis of the connector is perpendicular to a longitudinal axis of the conductive elements.

9. The actuator of claim 1, wherein the at least the first and second sub-assemblies, and the connector are embedded within an internal cavity formed into the body of the flexible member.

10. The actuator of claim 1, wherein the flexible member is integrally formed around the at least the first and second sub-assemblies, and the connector.

11. The actuator of claim 1, wherein at least the electrical input and electrical output provide an electrical contact that extends outside of the flexible member.

12. The actuator of claim 1, wherein the flexible member is selected from the group consisting of a wiper blade, a gasket, a seal, and a resilient member.

13. The actuator of claim 1, wherein the actuator is flexible such that it conforms to the shape of the flexible member during actuation and deformation of the flexible body.

14. A method comprising:
inducing an electrical current in an object comprising an actuator for an electro-expulsive residue disruption apparatus, the object comprising an actuator for the electro-expulsive disruption apparatus embedded within a flexible member comprising:
a first sub-assembly comprising a first electrically conductive element coupled to an electrical input at a first end of the first electrically conductive element;
a second sub-assembly comprising a second electrically conductive element coupled to an electrical output at a first end of the second electrically conductive element;
wherein the first and second sub-assemblies are mechanically independent.
a separate electrically conductive connector connecting a second end of the first electrically conductive element of the first sub-assembly to a corresponding second end of the second electrically conductive element of the second sub-assembly, thereby creating a conductive path from the electrical input to the electrical output, and wherein the connector is configured to allow the second end of the first sub-assembly and the second end of the second sub-assembly to move apart relative to each other;
wherein at least the first and second sub-assemblies, and the connector are embedded within a flexible member; and
wherein the first and second sub-assemblies are disposed in an orientation such that when electrical current flows through the conductive loop, at least a portion of each of the first and second sub-assemblies move apart relative to one another as a result of the magnetic fields created by the electrical current in the first and second sub-assemblies thereby causing the flexible member to undergo a flexural deformation.

15. The method of claim 14, wherein the first sub-assembly comprises a plurality of electrically conductive elements in a substantially stacked, parallel configuration.

16. The method of claim 15, wherein the second sub-assembly comprises a plurality of electrically conductive elements in a substantially stacked, parallel configuration.

17. The method of claim 16, wherein the connector is one of a plurality of connectors connecting second ends of pairs of electrically conductive elements, each pair comprising an electrically conductive element from the first sub-assembly element and an electrically conductive element from the second sub-assembly.

18. The method of claim 17, further comprising a second plurality of connectors connecting first ends of pairs of electrically conductive element, each pair comprising an electrically conductive element from the first sub-assembly and an electrically conductive element from the second sub-assembly.

19. The method of claim 14, wherein the connector is flexible and is selected from the group consisting of a wire and a U-shaped loop.

20. The method of claim 14, wherein a longitudinal axis of the connector is parallel to a longitudinal axis of the conductive elements.

21. The method of claim 14, wherein a longitudinal axis of the connector is perpendicular to a longitudinal axis of the conductive elements.

22. The method of claim 14, wherein the at least the first and second sub-assemblies, and the connector are embedded within an internal cavity formed into the body of the flexible member.

23. The method of claim 14, wherein the flexible member is integrally formed around the at least the first and second sub-assemblies, and the connector.

24. The method of claim 14, wherein at least the electrical input and electrical output provide an electrical contact that extends outside of the flexible member.

25. The method of claim 14, wherein the flexible member is selected from the group consisting of a wiper blade, a gasket, a resilient member, and a seal.

26. The method of claim 14, wherein the actuator is flexible such that it conforms to the shape of the flexible member during actuation and deformation of the flexible body.

27. An self-flexing flexible member comprising:
an elongated flexible body;
a flexible actuator contained within said body and comprising:
a first sub-assembly comprising a first electrically conductive element coupled to an electrical input at a first end of the first electrically conductive element,
a second sub-assembly comprising a second electrically conductive element coupled to an electrical output at a first end of the second electrically conductive element,
wherein the first and second sub-assemblies are independent,
a separate electrically conductive connector connecting a second end of the first electrically conductive element of the first sub-assembly to a corresponding second end of the second electrically conductive element of the second sub-assembly, thereby creating a conductive path from the electrical input to the electrical output, and wherein the connector is configured to allow the second end of the first sub-assembly and the second end of the second sub-assembly to move apart relative to each other;
wherein at least the first and second sub-assemblies, and the connector are embedded within a flexible member, and
wherein the first and second sub-assemblies are disposed in an orientation such that when electrical current flows through the conductive loop, at least a portion of each of the first and second sub-assemblies move apart relative to one another as a result of the magnetic fields created by the electrical current in the first and second sub-assemblies; and
wherein the flexible actuator is disposed within the flexible body such that movement of the actuator causes the flexible body to undergo a flexural deformation.
